(19) United States
(12) Patent Application Publication
(10) Pub. No.: US 2025/0046768 A1
(43) Pub. Date: Feb. 6, 2025

(54) SEMICONDUCTOR CHIPS AND SEMICONDUCTOR PACKAGES INCLUDING THE SAME

(71) Applicant: Samsung Electronics Co., Ltd., Suwon-si (KR)

(72) Inventor: Hansae Lim, Suwon-si (KR)

(21) Appl. No.: 18/440,991

(22) Filed: Feb. 14, 2024

(30) Foreign Application Priority Data
Aug. 2, 2023 (KR) 10-2023-0100893
Aug. 18, 2023 (KR) 10-2023-0108321

(51) Int. Cl. H01L 25/10; H01L 23/00; H10B 80/00

(52) U.S. Cl. CPC H01L 25/105; H01L 24/06; H01L 24/13; H01L 24/16; H01L 2224/06133; H01L 2224/13023; H01L 2224/16146; H01L 2224/16227; H01L 2225/1058; H01L 2924/1435; H10B 80/00

(57) ABSTRACT

A semiconductor chip according to some embodiments may include a main area, and an edge area that is positioned on a side of the main area in a first direction. On the main area, main area chip pads may be provided, and on the edge area, edge area chip pads may be provided. The edge area chip pads may be arranged such that two edge area chip pads immediately adjacent to each other in the first direction may be spaced apart from each other in a direction intersecting the first direction.

### CROSS-REFERENCE TO RELATED APPLICATIONS

This application claims priority to and the benefit of Korean Patent Application No. 10-2023-0100893 filed in the Korean Intellectual Property Office on Aug. 2, 2023, and to Korean Patent Application No. 10-2023-0108321, filed in the Korean Intellectual Property Office on Aug. 18, 2023, and the entire contents of the above-identified applications are incorporated by reference herein.

### TECHNICAL FIELD

The present disclosure relates to semiconductor chips and to semiconductor packages including the same.

### BACKGROUND

Semiconductor packages are packages of integrated circuit chips implemented in a form usable in electronic products. Typically, a semiconductor package is made by mounting semiconductor chips on a substrate such as printed circuit board (PCB). Semiconductor chips may be electrically coupled to the substrate through solder bumps and so on. During a mounting process, the solder bumps may have fluidity, which may cause adjacent solder bumps to come into contact with each other during the mounting process, resulting in short circuits.

### SUMMARY

The present disclosure attempts to provide a semiconductor chip having reduced defects and/or capable of preventing defects due to short circuits from occurring during a process of manufacturing a semiconductor package, and a semiconductor package including the same.

However, the effects of the embodiments of the present disclosure are not limited to the above-described object, and they can be variously expanded within the technical scope of the present disclosure.

A semiconductor chip according to some aspects may include: a main area; a first edge area that is positioned on an outer side of the main area in a first direction; main area chip pads arranged in the main area; and edge area chip pads arranged in the edge area. The edge area chip pads may be arranged such that first and second edge area chip pads immediately adjacent to each other in the first direction are spaced apart from each other in a direction intersecting the first direction.

A semiconductor chip according to some aspects may include a main area; a first edge area that is positioned on a first side of the main area in a first direction; and a second edge area that is positioned a second side of the main area that is opposite from the first side in the first direction; main area chip pads provided in the main area on a first line and a second line that extend in the first direction; and edge area chip pads provided in first and second edge areas. The edge area chip pads may be arranged such that two edge area chip pads immediately adjacent to each other in the first direction may be spaced apart from each other in a second direction intersecting the first direction.

A semiconductor package according to some aspects may include a substrate, a semiconductor chip on the substrate, and chip terminals that couple the semiconductor chip to the substrate. The semiconductor chip may include a main area; a first edge area that is positioned on an outer side of the main area in a first direction; main area chip pads arranged in the main area; and edge area chip pads arranged in the edge area. The edge area chip pads may be arranged such that first and second edge area chip pads immediately adjacent to each other in the first direction are spaced apart from each other in a direction intersecting the first direction.

According to some embodiments, it may be possible to prevent defects due to short circuits from occurring during a process of manufacturing a semiconductor package.

### BRIEF DESCRIPTION OF THE DRAWINGS

FIG. 1 is a cross-sectional view of a semiconductor package according to an embodiment.

FIG. 2 is a view illustrating a second surface of a semiconductor chip in FIG. 1.

FIG. 3 is a view illustrating a layout of data pad areas according to another embodiment.

FIG. 4 is a view illustrating a first edge area and a main area adjacent to the first edge area, shown in FIG. 2 and FIG. 3.

FIG. 5 is a view illustrating the boundary of a first edge area and a main area according to another embodiment.

FIG. 6 is a view illustrating some of main area chip pads and some of edge area chip pads.

FIG. 7 is a view illustrating a portion of a first surface of the substrate.

FIG. 8 is a view illustrating a state where edge area chip pads are positioned on mounting pads.

FIG. 9 is a view illustrating some of main area chip pads and some of edge area chip pads in a semiconductor chip according to a second embodiment.

FIG. 10 is a view illustrating some of main area chip pads and some of edge area chip pads in a semiconductor chip according to a third embodiment.

FIG. 11 is a view illustrating the boundary of a main area and an edge area in the semiconductor chip according to the third embodiment.

FIG. 12 is a view illustrating the boundary of a main area and an edge area in a semiconductor chip according to a fourth embodiment.

FIG. 13 is a cross-sectional view of a semiconductor package according to another embodiment.

### DETAILED DESCRIPTION

In the following detailed description, only certain embodiments of the present inventive concepts have been shown and described, simply by way of illustration. The present inventive concepts can be variously implemented and is not limited to the following embodiments.

The drawings and description are to be regarded as illustrative in nature and not restrictive. Like reference numerals designate like elements throughout the specification.

In addition, the size and thickness of each configuration shown in the drawings are arbitrarily shown for understanding and ease of description, but the present inventive concepts are not limited thereto. In the drawings, at least some of the thicknesses and/or dimensions of areas, layers, films, panels, regions, etc., may be exaggerated for clarity, understanding, and/or ease of description.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “on” a reference portion, the element is located above or below the reference portion, and it does not necessarily mean that the element is located “above” or “on” in a direction opposite to gravity.

In addition, unless explicitly described to the contrary, the word “comprise,”, and variations such as “comprises” or “comprising,” will be understood to imply the inclusion of stated elements but not the exclusion of any other elements.

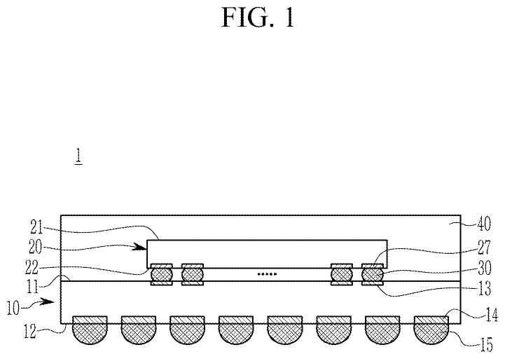

FIG. 1 is a cross-sectional view of a semiconductor package 1 according to some embodiments.

Referring to FIG. 1, the semiconductor package 1 according to some embodiments may include a substrate 10, a semiconductor chip 20, and a molding layer 40.

The substrate 10 may couple the semiconductor chip 20 and so on to an external component or device (not shown) outside the semiconductor package 1. The substrate 10 may be a printed circuit board, etc. The substrate 10 has a first surface 11 and a second surface 12 positioned in opposite directions so as to face each other. In FIG. 1, it is shown that the first surface 11 of the substrate 10 is positioned so as to face upward and the second surface 12 of the substrate 10 is positioned so as to face downward. The first surface 11 of the substrate 10 may be referred to as the upper surface of the substrate 10, and the second surface 12 of the substrate 10 may be referred to as the lower surface of the substrate 10. Further, the direction in which the upper surface and the lower surface are spaced apart from each other may be referred to as the upward and downward direction of the substrate 10, and may be referred to as the vertical direction.

The substrate 10 may contain an insulating material. The insulating material may be a thermosetting resin such as epoxy resin, a thermoplastic resin such as polyimide, etc. Alternatively, the insulating material may be an impregnated reinforcement material, such as impregnated glass fiber or an impregnated inorganic filler. For example, as the insulating material, prepreg, Ajinomoto build-up film (ABF), FR-4, a bismaleimide triazine (BT) resin, and so on may be used. In the inner region of the substrate 10, wiring structures and so on may be provided, which are not shown in FIG. 1. On the upper surface and lower surface of the substrate 10, passivation layers (not shown) may be positioned. The passivation layers may be formed of solder resist, etc.

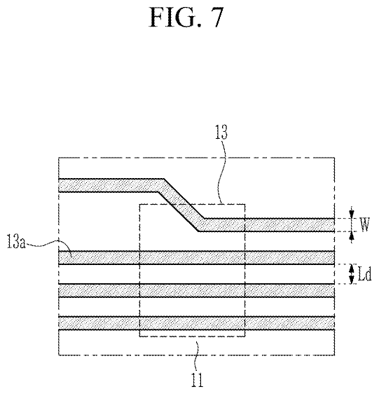

A mounting pad 13 may be positioned on the first surface 11 of the substrate 10. The mounting pad 13 may expose at least some areas of wiring lines (reference numeral “13a” in FIG. 7) to an outside of the substrate 10. In other words, on at least some areas of the wiring lines 13a positioned on the first surface 11 of the substrate 10, the passivation layers may not be formed such that the mounting pad 13 can be formed so as to expose the wiring lines 13a on the areas without the passivation layers to the outside of the substrate 10. The mounting pad 13 may be formed of a conductive material. The mounting pad 13 may be formed of a metallic material. For example, the mounting pad 13 may be formed of copper (Cu), silver (Ag), palladium (Pd), aluminum (Al), nickel (Ni), titanium (Ti), gold (Au), platinum (Pt), an alloy thereof, etc. A plurality of mounting pads 13 may be provided.

A connection pad 14 may be positioned on the second surface 12 of the substrate 10. The connection pad 14 may be exposed to the outer space of the substrate 10. The connection pad 14 may be formed of a conductive material. The connection pad 14 may be formed of a metallic material. For example, the connection pad 14 may be formed of copper (Cu), silver (Ag), palladium (Pd), aluminum (Al), nickel (Ni), titanium (Ti), gold (Au), platinum (Pt), an alloy thereof, etc. A plurality of connection pads 14 may be provided. Each connection pad 14 may be coupled to a connection terminal 15. The connection terminal 15 may be a solder ball, etc., and may be attached to the connection pad 14.

The semiconductor chip 20 may be positioned on the first surface 11 of the substrate 10. The semiconductor chip 20 may be a memory chip, etc. For example, the semiconductor chip 20 may be a DRAM device, an SDRAM device, an RRAM device, a PRAM device, an MRAM device, or an STT-MRAM (Spin Transfer Torque MRAM) device, an EDP device, an FRAM device, a graphic DRAM device, a ReRAM device, etc. The semiconductor chip 20 may be coupled to the upper surface of the mounting pad 13. The semiconductor chip 20 may be mounted on the substrate 10 in a flip-chip manner. The semiconductor chip 20 may have a first surface 21 and a second surface 22 positioned in opposite directions so as to face each other. In FIG. 1, it is shown that the first surface 21 of the semiconductor chip 20 is positioned so as to face upward and the second surface 22 of the semiconductor chip 20 is positioned so as to face downward (e.g., toward the substrate 10). The first surface 21 of the semiconductor chip 20 may be referred to as the upper surface of the semiconductor chip 20, and the second surface 22 of the semiconductor chip 20 may be referred to as the lower surface of the semiconductor chip 20. In other words, the semiconductor chip 20 may be manufactured in a state where the second surface 22 faces upward. Thereafter, the semiconductor chip 20 may be flipped such that the second surface 22 faces downward, and then the semiconductor chip 20 may be mounted on the substrate 10.

On the second surface 22 of the semiconductor chip 20, a chip pad 27 may be positioned. The chip pad 27 may be coupled to the mounting pad 13 by a chip terminal 30. The chip terminal 30 may be a solder bump, a solder ball, etc. Further, the chip terminal 30 may include a metal pillar structure.

The molding layer 40 may be formed on the first surface 11 of the substrate 10. The molding layer 40 may surround the outer side of the semiconductor chip 20. The molding layer 40 may protect the semiconductor chip 20 and so on from external impact, heat, and the like. The molding layer 40 may contain an insulating polymeric material such as an epoxy molding compound (EMC). The molding layer 40 may contain a thermosetting resin such as epoxy resin, a thermoplastic resin such as polyimide, or a thermosetting resin or a thermoplastic resin containing a reinforcement material such as a filler, etc. For example, the molding layer 40 may contain ABF (Ajinomoto Build-up Film), FR-4, BT (Bismaleimide Triazine) resin, etc.

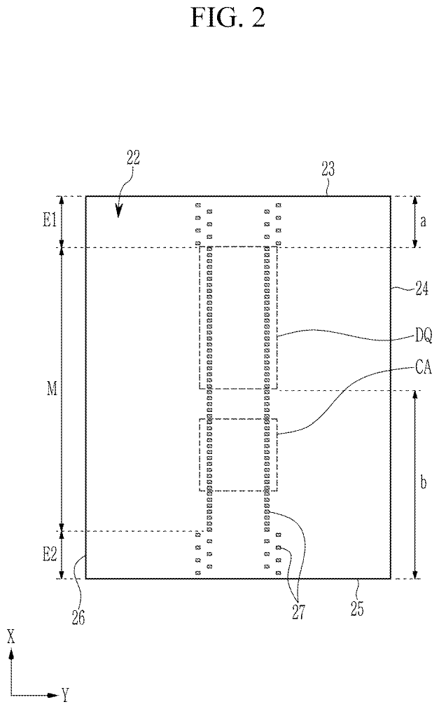

FIG. 2 is a view illustrating the second surface 22 of the semiconductor chip 20 in FIG. 1.

Referring to FIG. 2, at the outer periphery of the second surface 22 of the semiconductor chip 20, edges 23, 24, 25, and 26 are positioned. In other words, side surfaces of the semiconductor chip 20 may be positioned between the first surface 21 and the second surface 22. Further, in the region where the side surfaces and the second surface 22 meet, the edges 23, 24, 25, and 26 are positioned. At the outer periphery of the second surface 22 of the semiconductor chip 20, the first edge 23, the second edge 24, the third edge 25, and the fourth edge 26 may be positioned. The first edge 23 and the third edge 25 may be positioned so as to face each other. The second edge 24 and the fourth edge 26 may be positioned so as to face each other.

The direction in which the first edge 23 and the third edge 25 face each other may be referred to as a first direction X. The direction in which the second edge 24 and the fourth edge 26 face each other and which intersects the first direction X may be referred to as a second direction Y. The length of the semiconductor chip 20 in the first direction X and the length of the semiconductor chip in the second direction Y may be different. For example, the length of semiconductor chip 20 in the first direction X may be longer than the length of the semiconductor chip in the second direction Y.

The second surface 22 of the semiconductor chip 20 has a main area M and edge areas E1 and E2.

The main area M may be positioned at the center area of the second surface 22 of the semiconductor chip 20 in the first direction X.

The edge areas E1 and E2 may be positioned on the outer sides from the main area M in the first direction X. The edge areas E1 and E2 may be positioned on both sides of the main area M in the first direction X, respectively.

The edge areas E1 and E2 may include a first edge area E1 and a second edge area E2. The first edge area E1 is positioned between the main area M and the first edge 23 in the first direction X. The second edge area E2 is positioned between the main area M and the third edge 25 in the first direction X. In other words, the first edge 23 is positioned on the outer side of the first edge area E1 in the first direction X. The third edge 25 is positioned on the outer side of the second edge area E2 in the first direction X.

On the second surface 22 of the semiconductor chip 20, a plurality of chip pads 27 may be arranged. The chip pads 27 may be arranged along the first direction X. Two chip pads 27 may be arranged in the second direction Y so as to be spaced apart from each other. The chip pads 27 may be positioned in the center area in the second direction Y. On the second surface 22 of the semiconductor chip 20, a data pad area DQ and a command/address pad area CA are positioned. On the data pad area DQ, data pads may be arranged. The data pads receive and output data signals. On the command/address pad area CA, command/address pads may be arranged. The command/address pads receive and output command signals, such as data strobe signals, data mask signals, chip select signals, a clock signal, write enable signals, RAS signals, and CAS signals, and address signals.

The data pad area DQ may be positioned in the main area M. The command/address pad area CA may be positioned in the main area M.

At least one end of the data pad area DQ in the first direction X may be positioned at a boundary between the main area M and one of the edge areas E1 and E2. In FIG. 2, it is shown that one end of the data pad area DQ is positioned at the boundary of the main area M and the first edge area E1.

The length a of the first edge area E1 in the first direction X may be in a range of 6% or more and 10% or less (or a range between 6%-10%, inclusive) of the total length of the semiconductor chip 20 in the first direction X. In other words, of the lengths a and b in FIG. 2 in the first direction X between the data pad area DQ and the edges 23 and 25, the shorter length a may be in a range 6% or more and 10% or less of the total length of the semiconductor chip 20 in the first direction X.

The length of the second edge area E2 in the first direction X may be in a range 6% or more and 10% or less (or a range between 6%-10%, inclusive) of the total length of the semiconductor chip 20 in the first direction X. The length of the second edge area E2 may correspond to the length of the first edge area E1. In other words, within an error range which may occur in the manufacturing process, the length of the second edge area E2 may be regarded as being the same as or equal to the length of the first edge area E1.

On the edge areas E1 and E2, power pads, control pads, and so on, such as e.g., VDD pads, VSS pads, VPP pads, ZQ pads, ODT pads, and the like may be arranged.

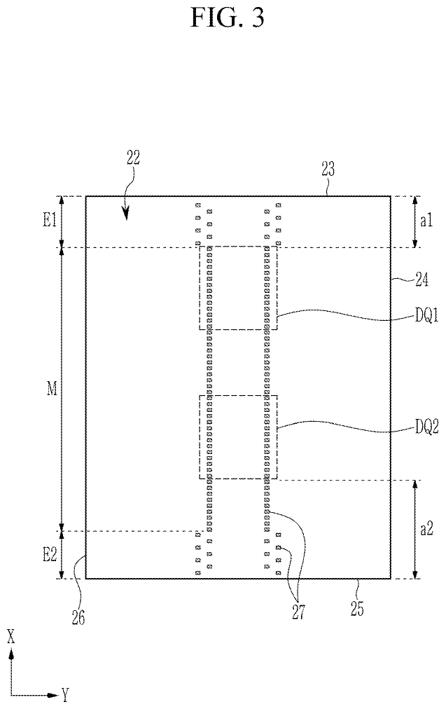

FIG. 3 is a view illustrating a layout of data pad areas DQ1 and DQ2 according to some embodiments.

Referring to FIG. 3, the data pad areas DQ1 and DQ2 may include a first data pad area DQ1 and a second data pad area DQ2. The first data pad area DQ1 and the second data pad area DQ2 may be positioned so as to be spaced apart from each other in the first direction X. The first data pad area DQ1 and the second data pad area DQ2 may be positioned in the main area M. In at least one of the first data pad area DQ1 and the second data pad area DQ2, at least one edge in the first direction X facing the edge 23 or 25 may be positioned at a boundary between the main area M and one of the edge areas E1 or E2.

In FIG. 3, it is illustrated that the distance between the first data pad area DQ1 and the first edge 23 is shorter than the distance between the second data pad area DQ2 and the third edge 25. In other words, in the first direction X, the first data pad area DQ1 may be positioned closer to the edge 23 of the second surface 22 of the semiconductor chip 20 as compared to where the second data pad area DQ2 is positioned adjacent to the edge 25. Accordingly, one end of the first data pad area DQ1 may be positioned at the boundary of the main area M and the first edge area E1.

The first edge area E1, the second edge area E2, and the main area M may be identical to or similar to those described with reference to FIG. 2, except that the data pad areas DQ1 and DQ2 include the first data pad area DQ1 and the second data pad area DQ2. The length of the first edge area E1 in the first direction X may be in a range 6% or more and 10% or less of the total length of the semiconductor chip 20 in the first direction X. In other words, of the length a1 between the first data pad area DQ1 and the first edge 23 and the length a2 between the second data pad area DQ2 and the third edge 25 in the first direction X, the shorter length a1 may be in a range 6% or more and 10% or less of the total length of the semiconductor chip 20 in the first direction X.

Further, the length of the second edge area E2 in the first direction X may be in a range 6% or more and 10% or less of the total length of the semiconductor chip 20 in the first direction X. The length of the second edge area E2 may correspond to the length of the first edge area E1. In other words, within an error range which may occur in the manufacturing process, the length of the second edge area E2 may be regarded as being the same as or equal to the length of the first edge area E1.

In FIG. 3, any command/address pad area CA is not shown for convenience. Identically or similarly to FIG. 2, a command/address pad area CA may be positioned in the main area M.

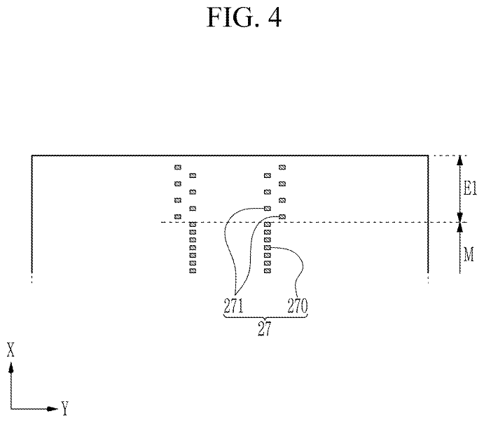

FIG. 4 is a view illustrating the first edge area E1 and the main area M adjacent to the first edge area E1, shown in FIG. 2 and FIG. 3.

Referring to FIG. 4, the chip pads 27 may include main area chip pads 270 and edge area chip pads 271.

The main area chip pads 270 may be arranged on the main area M. The main area chip pads 270 may be arranged in two lines (e.g., first and second lines) along the first direction X. The first and second lines in which the main area chip pads 270 are arranged may be positioned so as to be spaced apart from each other by a preset distance in the second direction Y. The main area chip pads 270 on the first of the two lines and the main area chip pads 270 on the second line of the two lines may be positioned so as to face each other in the second direction Y.

The edge area chip pads 271 may be provided on the edge areas E1 and E2, e.g., on the first edge area E1 and the second edge area E2. The edge area chip pads 271 may be provided or arranged in a zigzag manner with respect to the first direction X. In other words, the edge area chip pads 271 are disposed such that two edge area chip pads adjacent to each other with a shortest distance in the first direction X (that is, immediately adjacent to each other) may be spaced apart from each other in the second direction Y.

The boundaries of the edge areas E1 and E2 and the main area M may pass through ends positioned closer to the edge areas E1 and E2 among the ends of main area chip pads that are closest to the edge areas E1 and E2 among the main area chip pads 270. In other words, the length of the first edge area E1 may be the distance between the first edge 23 and the main area chip pad that is positioned closest to the first edge area E1 among the main area chip pads 270. Similarly, the length of the second edge area E2 may be the distance between the third edge 25 and the main area chip pad that is positioned closest to the second edge area E2 among the main area chip pads 270.

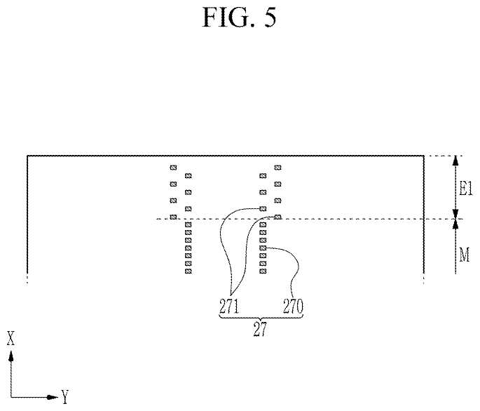

FIG. 5 is a view illustrating the boundary of the first edge area E1 and the main area M according to some embodiments.

Referring to FIG. 5, the boundaries of the edge areas E1 and E2 and the main area M may pass through ends positioned closer to the main area M among the ends of edge area chip pads that are closest to the main area M among the edge area chip pads 271. In other words, the length of the first edge area E1 motioned above may be the distance between the first edge 23 and the edge area chip pad that is positioned closest to the main area M among the edge area chip pads 271 disposed on the first edge area E1. Similarly, the length of the second edge area E2 mentioned above may be the distance between the third edge 25 and the edge area chip pad that is positioned closest to the main area M among the edge area chip pads 271 disposed on the second edge area E2.

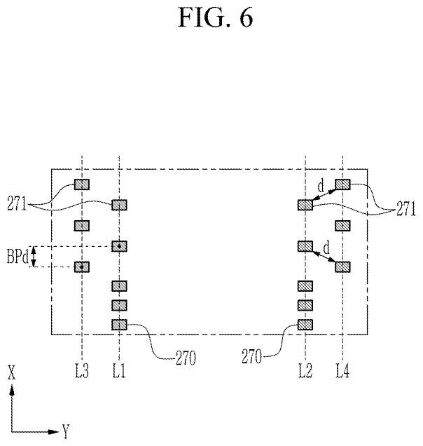

FIG. 6 is a view illustrating some of the main area chip pads 270 and some of the edge area chip pads 271.

Referring to FIG. 6, the main area chip pads 270 may be arranged in a first line L1 and a second line L2.

The first line L1 and the second line L2 may extend in the first direction X. The first line L1 and the second line L2 may be positioned in the center area of the second surface 22 of the semiconductor chip 20 in the second direction Y. The first line L1 and the second line L2 may be positioned so as to be spaced apart from each other in the second direction Y. The main area chip pads 270 may be arranged on the first line L1 and the second line L2. The main area chip pads 270 on the first line L1 and the second line L2 may be arranged so as to face or overlap each other in the second direction Y. The distances between the main area chip pads 270 that are arranged on the first line L1 and spaced apart from each other (in the first direction X) may correspond to the distances between the main area chip pads 270 arranged on the second line L2 and spaced apart from each other (in the first direction X).

The edge area chip pads 271 may be arranged on the first line L1, the second line L2, a third line L3, and a fourth line LA. The lines L3 and L4 on which the edge area chip pads 271 are arranged may be positioned so as to be closer to one of the first line L1 and the second line L2 than to the other.

The third line L3 and the fourth line L4 may extend in the first direction X. The third line L3 may be positioned on the opposite side of the first line L1 with respect to the second line L2. In the second direction Y, the distance between the third line L3 and the first line L1 may be shorter than the distance between the first line L1 and the second line L2.

The fourth line L4 is positioned on the opposite side of the second line L2 with respect to the first line L1. In the second direction Y, the distance between the fourth line L4 and the second line L2 may be shorter than the distance between the first line L1 and the second line L2. The distance between the fourth line L4 and the second line L2 may correspond to or equal the distance between the third line L3 and the first line L1.

The edge area chip pads 271 may be alternately arranged on the first line L1 and the third line L3 along the first direction X. Further, the edge area chip pads 271 may be alternately arranged on the second line L2 and the fourth line L4 along the first direction X.

Among the edge area chip pads 271, two edge area chip pads 271 closest to the main area M may be provided on the third line L3 and the fourth line L4, respectively.

The distance BPd in the first direction X by which the center areas of two edge area chip pads 271 adjacent to each other in a direction oblique to the first direction X and the second direction Y are spaced apart from each other (that is, two edge area chip pads immediately adjacent to each other) may be in a range between 25 μm and 65 μm, inclusive. In other words, the distance BPd in the first direction X by which the center areas of two edge area chip pads 271 on the first line L1 and the third line L3 are spaced apart from each other may be in a range between 25 μm and 65 μm, inclusive. The distance BPd in the first direction X by which the center areas of two edge area chip pads 271 on the second line L2 and the fourth line L4 are spaced apart from each other may be in a range between 25 μm and 65 μm, inclusive.

The distance d between two edge area chip pads 271 adjacent to each other in a direction oblique to the first direction X and the second direction Y may be equal to or greater than 30 μm. In this case, the distance d between two edge area chip pads 271 may be the shortest distance between the outer ends of one of the two edge area chip pads 271 and the outer ends of the other. In other words, the distance d between two edge area chip pads 271 on the first line L1 and the third line L3 so as to be adjacent to each other may be equal to or greater than 30 μm. Further, the distance d between two edge area chip pads 271 on the second line L2 and the fourth line L4 so as to be adjacent to each other may be equal to or greater than 30 μm.

FIG. 7 is a view illustrating a portion of the first surface 11 of the substrate 10.

Referring to FIG. 7, as described above, in the region of the substrate 10 on the first surface (11) side, the wiring lines 13a may be provided. The width W of the wiring lines 13a may be in a range between 20 μm and 30 μm, inclusive. In the area where a mounting pad 13 is provided, the distance Ld between a wiring line 13a and another wiring line 13a may be in a range between 30 μm and 50 μm, inclusive.

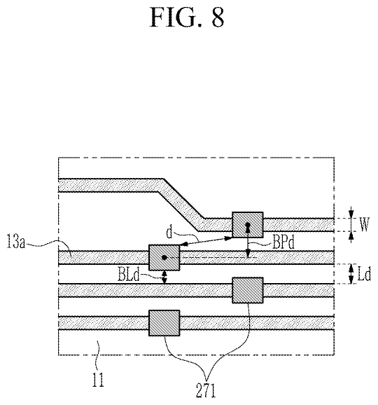

FIG. 8 is a view illustrating an arrangement where edge area chip pads 271 are disposed on a mounting pad 13.

The state of the chip pads 27 as viewed in a direction toward the first surface 11 of the substrate 10 is shown. Further, for ease of illustration, portions of the semiconductor chip 20 other than the edge area chip pads 271 are not shown.

Referring to FIG. 8, when the semiconductor chip 20 is on the substrate 10, the distance BLd between the outer end of an edge area chip pad 271 and an adjacent wiring line 13a may be equal to or greater than 25 μm. Specifically, since the edge area chip pads 271 are provided in a zigzag manner, between two edge area chip pads 271 facing each other in the first direction X, a wiring line 13a may be arranged. Further, between the outer end of the edge area chip pad 271 and the adjacent wiring line 13a, a sufficient distance may be secured.

Accordingly, it may be possible to prevent short circuiting of the chip terminals 30 from occurring between two edge area chip pads 271 facing each other in the first direction X.

Further, as described above, the distance d between two edge area chip pads 271 adjacent to each other in a direction oblique to the first direction X and the second direction Y may be equal to or greater than 30 μm. Accordingly, it may be possible to prevent short-circuiting of the chip terminals 30 from occurring between two edge area chip pads 271 disposed adjacent to each other in a direction oblique to the first direction X and the second direction Y.

Specifically, the thermal expansion coefficients of the semiconductor chip 20 and the substrate 10 may be different as their materials are different. Accordingly, in the process of mounting the semiconductor chip 20 on the substrate 10, warpage of the substrate 10 and the semiconductor chip 20 may occur. The warpage may cause skewing of the chip terminals 30 having fluidity, resulting in short-circuiting between the chip terminals 30. Particularly, warpage and short-circuiting between the chip terminals 30 as described above may occur mainly in the edge areas of the semiconductor chip 20 adjacent to the side surface.

However, in the semiconductor chip 20 according to the above-described embodiments, sufficient distances may be secured between the edge area chip pads 271, and short-circuiting between the chip terminals 30 is prevented.

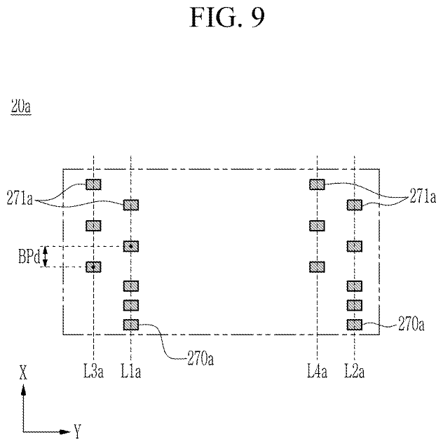

FIG. 9 is a view illustrating some of main area chip pads 270a and some of edge area chip pads 271a in a semiconductor chip 20a according to some embodiments.

Referring to FIG. 9, the main area chip pads 270a may be on a first line L1a and a second line L2a. The first line L1a, the second line L2a, and the main area chip pads 270a may be identical or similar to the first line L1, the second line L2, and the main area chip pads 270 in FIG. 6, and thus a redundant description will not be made here in the interest of brevity.

The edge area chip pads 271a may be on the first line L1a, the second line L2a, a third line L3a, and a fourth line L4a

The lines L3a and L4a on which the edge area chip pads 271a are arranged may be positioned so as to be closer to one of the first line L1a and the second line L2a than to the other.

The third line L3a and the fourth line L4a may extend in the first direction X. At least one of the third line L3a and the fourth line LAa may be positioned between the first line L1a and the second line L2a. In FIG. 9, it is shown that the third line L3a is positioned on the opposite side of the second line L2a with respect to the first line L1a and the fourth line LAa is positioned between the first line L1a and the second line L2a, but the present disclosure is not limited thereto.

In the second direction Y, the distance between the third line L3a and the first line L1a may be shorter than the distance between the first line L1a and the second line L2a.

In the second direction Y, the distance between the fourth line LAa and the second line L2a may be shorter than the distance between the first line L1a and the second line L2a. The distance between the second line L2a and the fourth line L4a may correspond to or equal the distance between the first line L1a and the third line L3a.

The edge area chip pads 271a may be alternately arranged on the first line L1a and the third line L3a along the first direction X. Further, the edge area chip pads 271a may be alternately arranged on the second line L2a and the fourth line LAa along the first direction X.

Among the edge area chip pads 271a, two edge area chip pads 271a closest to the main area M may be on the third line L3a and the fourth line L4a, respectively.

The distance BPd in the first direction X by which the center areas of two edge area chip pads 271a that are adjacent to each other in a direction oblique to the first direction X and the second direction Y (that is, two edge area chip pads 271a immediately adjacent to each other) are spaced apart from each other may be in a range between 25 μm and 65 μm, inclusive. In other words, the distance BPd in the first direction X by which the center areas of two edge area chip pads 271a arranged on the first line L1a and the third line L3a so as to be adjacent to each other are spaced apart from each other may be in a range between 25 μm and 65 μm, inclusive. Further, the distance BPd in the first direction X by which the center areas of two edge area chip pads 271a are arranged on the second line L2a and the fourth line L4a so as to be adjacent to each other are spaced apart from each other may be in a range between 25 μm and 65 μm, inclusive.

The distance between two edge area chip pads 271a adjacent to each other in a direction oblique to the first direction X and the second direction Y may be equal to or greater than 30 μm. In this case, the distance between two edge area chip pads 271a may be the shortest distance between the outer ends of one of the two edge area chip pads 271a and the outer ends of the other. In other words, the distance between two edge area chip pads 271a on the first line L1a and the third line L3a so as to be adjacent to each other may be equal to or greater than 30 μm. Further, the distance between two edge area chip pads 271a on the second line L2a and the fourth line L4a so as to be adjacent to each other may be equal to or greater than 30 μm.

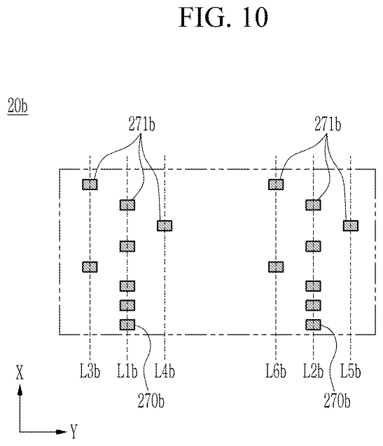

FIG. 10 is a view illustrating some main area chip pads 270b and some edge area chip pads 271b in a semiconductor chip 20b according to some embodiments.

Referring to FIG. 10, the main area chip pads 270b may be on a first line L1b and a second line L2b. The first line L1b, the second line L2b, and the main area chip pads 270b may be identical or similar to the first line L1, the second line L2, and the main area chip pads 270 in FIG. 6, and thus a redundant description will not be made here in the interest of brevity.

The edge area chip pads 271b may be on the first line L1b, the second line L2b, a third line L3b, a fourth line L4b, a fifth line L5b, and a sixth line L6b.

The lines L3b, L4b, L5b, and L6b on which the edge area chip pads 271b are arranged may be positioned so as to be closer to one of the first line L1a and the second line L2a than to the other.

The third line L3b, the fourth line L4, the fifth line L5b, and the sixth line L6b may extend in the first direction X.

The third line L3b may be positioned on the opposite side of the first line L1b with respect to the second line L2b. In the second direction Y, the distance between the third line L3b and the first line L1b may be shorter than the distance between the first line L1b and the second line L2b.

The fourth line L4b may be positioned between the first line L1b and the second line L2b. In the second direction Y, the distance between the fourth line L4b and the first line Lib may be shorter than the distance between the fourth line L4b and the second line L2b. The distance between the fourth line L4b and the first line L1b may correspond to the distance between the third line L3b and the first line L1b.

The fifth line L5b may be positioned on the opposite side of the second line L2b with respect to the first line L1b. In the second direction Y, the distance between the fifth line L5b and the second line L2b may be shorter than the distance between the first line L1b and the second line L2b. The distance between the fifth line L5b and the second line L2b may correspond to the distance between the third line L3b and the first line L1b.

The sixth line L6b may be positioned between the first line L1b and the second line L2b. In the second direction Y, the distance between the sixth line L6b and the second line L2b may be shorter than the distance between the sixth line L6b and the first line L1b. The distance between the sixth line L6b and the second line L2b may correspond to the distance between the fifth line L5b and the second line L2b.

The edge area chip pads 271b may be alternately arranged on at least two of the first line L1b, the third line L3b, and the fourth line L4b along the first direction X. In some embodiments, the edge area chip pads 271b may be arranged on all of the first line L1b, the third line L3b, and the fourth line L4b along the first direction X.

Further, the edge area chip pads 271b may be alternately arranged on at least two of the second line L2b, the fifth line L5b, and the sixth line L6b along the first direction X. In some embodiments, the edge area chip pads 271b may be arranged on all of the second line L2b, the fifth line L5b, and the sixth line L6b along the first direction X

Among the edge area chip pads 271b, two edge area chip pads 271b closest to the main area M may be on one of the third line L3b and the fourth line L4b and one of the fifth line L5b and the sixth line L6b, respectively.

The distance in the first direction X by which the center areas of two edge area chip pads 271b adjacent to each other in a direction oblique to the first direction X and the second direction Y are spaced apart from each other may be in a range between 25 μm and 65 μm, inclusive. In other words, the distance in the first direction X by which the center areas of two edge area chip pads 271b on two of the first line L1b, the third line L3b, and the fourth line L4b, respectively, so as to be adjacent to each other in a direction oblique to the first direction X and the second direction Y are spaced apart from each other may be in a range between 25 μm and 65 μm, inclusive.

Further, the distance in the first direction X by which the center areas of two edge area chip pads 271b on two of the second line L2b, the fifth line L5b, and the sixth line L6b, respectively, so as to be adjacent to each other in a direction oblique to the first direction X and the second direction Y are spaced apart from each other may be in a range between 25 μm and 65 μm, inclusive.

The distance between two edge area chip pads 271b adjacent to each other in a direction oblique to the first direction X and the second direction Y may be equal to or greater than 30 μm. In this case, the distance between two edge area chip pads 271b may be the shortest distance between the outer ends of one of the two edge area chip pads 271b and the outer ends of the other.

In other words, the distance between two edge area chip pads 271b on two of the first line L1b, the third line L3b, and the fourth line L4b, respectively, so as to be adjacent to each other in a direction oblique to the first direction X and the second direction Y may be equal to or greater than 30 μm. Further, the distance between two edge area chip pads 271b disposed on two of the second line L2b, the fifth line L5b, and the sixth line L6b, respectively, so as to be adjacent to each other in a direction oblique to the first direction X and the second direction Y may be equal to or greater than 30 μm.

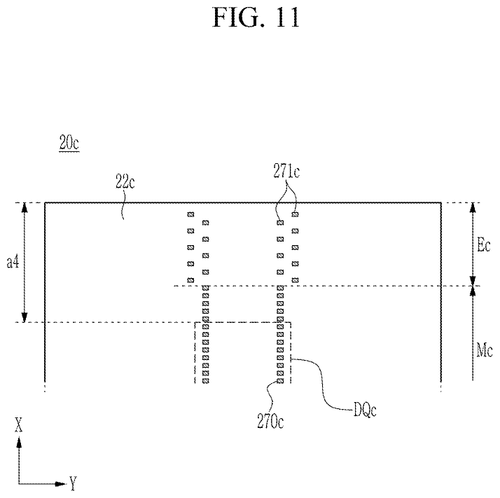

FIG. 11 is a view illustrating the boundary of a main area Mc and an edge area Ec in a semiconductor chip 20c according to some embodiments.

Referring to FIG. 11, a data pad area DQc may be positioned in the main area Mc. The data pad area DQc may be positioned so as to be spaced apart from the boundaries of the main area Mc and edge areas Ec. Further, as described above with reference to FIG. 3, the data pad area DQc may be divided into two or more sections. In this case, a section of the data pad area DQc facing the first edge 23 and a section of the data pad area facing the third edge 25 may be positioned so as to be spaced apart from the edge areas Ec, respectively.

Further, the shorter length of the distance between the data pad area DQc and the first edge 23 and the distance between the data pad area DQc and the third edge 25 may be longer than the length of an edge area Ec in the first direction X.

Accordingly, between the boundary of the main area Mc and an edge area Ec and the data pad area DQc, at least one main area chip pad 270c may be positioned.

Further, the shorter length of the distance between the data pad area DQc and the first edge 23 and the distance between the data pad area DQc and the third edge 25 may be 10% or more of the total length of the semiconductor chip 20c in the first direction X. The length of an edge area Ec in the first direction X may be in a range between 6% and 10%, inclusive of the total length of the semiconductor chip 20c in the first direction X. Preferably, the length of an edge area Ec in the first direction X may be in a range between 9% 10%, inclusive or less of the total length of the semiconductor chip 20c in the first direction X.

The arrangement of the main area chip pads 270c on the main area Mc and the arrangement of edge area chip pads 271c on the edge areas Ec are identical or similar to those described above with reference to FIG. 2 to FIG. 10, and thus a redundant description will not be made here in the interest of brevity.

Further, the criteria for the boundaries of the edge areas Ec and the main area Mc are identical or similar to those described above with reference to FIG. 4 and FIG. 5, and thus a redundant description will not be made.

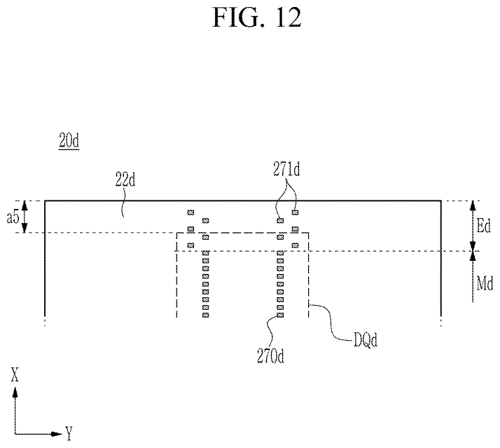

FIG. 12 is a view illustrating the boundary of a main area Md and an edge area Ed in a semiconductor chip 20d according to some embodiments.

Referring to FIG. 12, a portion of a data pad area DQd may be positioned in an edge area Ed.

In other words, at least one of both ends of the data pad area DQd in the first direction X may be positioned inside an edge area Ed.

Further, as described above with reference to FIG. 3, the data pad area DQd may be divided into two or more sections. In this case, at least one of a section of the data pad area DQd facing the first edge 23 and a section of the data pad area facing the third edge 25 may be positioned inside an edge area Ed. Further, at least one length a5 of the distance between the data pad area DQd and the first edge 23 and the distance between the data pad area DQd and the third edge 25 may be shorter than the length of an edge area Ed in the first direction X.

Accordingly, at least one of the boundaries of the main area Md and the edge areas Ed may cross the data pad area DQd. Further, the shorter length a5 of the distance between the data pad area DQd and the first edge 23 and the distance between the data pad area DQd and the third edge 25 may be 6% or less of the total length of the semiconductor chip 20d in the first direction X. As an example, the length of an edge area Ed in the first direction X may be in a range between 6% and 7%, inclusive, of the total length of the semiconductor chip 20d in the first direction X.

The arrangement of the main area chip pads 270d on the main area Md and the arrangement of edge area chip pads 271d on the edge areas Ed may be identical or similar to those described above with reference to FIG. 2 to FIG. 10, and thus a redundant description will not be made here in the interest of brevity.

Further, the criteria for the boundaries of the edge areas Ed and the main area Md are identical or similar to those described above with reference to FIG. 4 and FIG. 5, and thus a redundant description will not be made.

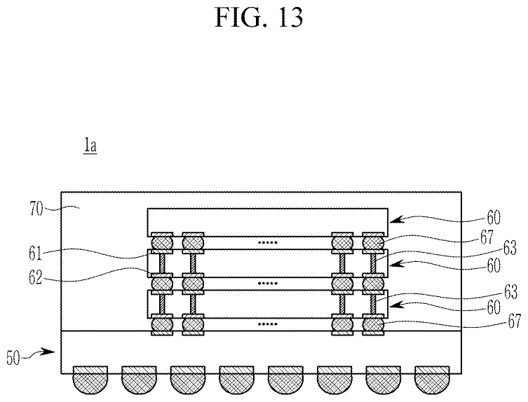

FIG. 13 is a cross-sectional view of a semiconductor package 1a according to some embodiments.

Referring to FIG. 13, the semiconductor package 1a according to some embodiments may include a substrate 50, a plurality of semiconductor chips 60, and a molding layer 70.

The substrate 50 may be identical or similar to the substrate 10 in FIG. 1, and thus a redundant description of the substrate 50 will not be made here in the interest of brevity.

Among the plurality of semiconductor chips 60, the semiconductor chips 60 other than the uppermost semiconductor chip 60 may include upper chip pads 61 and lower chip pads 62. Further, the uppermost semiconductor chip 60 may include lower chip pads 62. Among the plurality of semiconductor chips 60, the semiconductor chips 60 other than the uppermost semiconductor chip 60 may include through-hole vias 63 which may couple the upper chip pads 61 and the lower chip pads 62. Further, chip terminals 67 may be coupled to the lower chip pads 62 of the semiconductor chips 60. Accordingly, the semiconductor chips 60 may be coupled to the lower semiconductor chips 60 or the substrate 50 by the lower chip pads 62 and the chip terminals 67.

The lower chip pads 62 of the semiconductor chips 60 may have the structures of the chip pads 27, 270a, 271a, 270b, 271b, 270c, 271c, 270d, and 271d described above with reference to FIGS. 2 to 6 and FIGS. 9 to 12.

Further, the upper chip pads 61 of the semiconductor chips 60 may have the structures of the chip pads 27, 270a, 271a, 270b, 271b, 270c, 271c, 270d, and 271d described above with reference to FIGS. 2 to 6 and FIGS. 9 to 12.

The molding layer 70 may surround the outer side of the semiconductor chip 60. The molding layer 70 may be identical or similar to the molding layer 40 in FIG. 1, and thus a redundant description of the molding layer will not be made here in the interest of brevity.

While the inventive concepts disclosed herein have been described in connection with what is some examples of embodiments, it is to be understood that the inventive concepts are not limited to the disclosed embodiments. On the contrary, it is intended that the present disclosure covers various modifications and equivalent arrangements included within the scope of the appended claims.

What is claimed is:

1. A semiconductor chip comprising:
a main area;
an edge area that is positioned on an outer side of the main area in a first direction;
main area chip pads arranged in the main area; and
edge area chip pads arranged in the edge area,
wherein the edge area chip pads are arranged such that first and second edge area chip pads immediately adjacent to each other in the first direction are spaced apart from each other in a direction intersecting the first direction.

2. The semiconductor chip of claim 1, wherein
the main area chip pads are arranged in a first line and a second line, and
the first line and the second line extend in the first direction.

3. The semiconductor chip of claim 1, further comprising a data pad area in the main area.

4. The semiconductor chip of claim 3, wherein a first end of the data pad area in the first direction is positioned at a boundary of the main area and the edge area.

5. The semiconductor chip of claim 4, wherein a length of the edge area in the first direction is in a range between 6% and 10%, inclusive, of a total length of the semiconductor chip in the first direction.

6. The semiconductor chip of claim 3, wherein at least one main area chip pad is arranged between the data pad area and a boundary of the main area and the edge area.

7. The semiconductor chip of claim 6, wherein a distance in the first direction between the data pad area and an edge positioned on a side of the edge area opposite from the main area is 10% or more of a total length of the semiconductor chip in the first direction.

8. The semiconductor chip of claim 6, wherein a length of the edge area in the first direction is in a range between 9% and 10%, inclusive, of a total length of the semiconductor chip in the first direction.

9. The semiconductor chip of claim 3, wherein a portion of the data pad area is positioned in the edge area.

10. The semiconductor chip of claim 9, wherein a distance in the first direction between the data pad area and an edge positioned on a side of the edge area opposite from the main area is 6% or less of a total length of the semiconductor chip in the first direction.

11. The semiconductor chip of claim 9, wherein a length of the edge area in the first direction is in a range between 6% and 7%, inclusive, of a total length of the semiconductor chip in the first direction.

12. A semiconductor chip comprising:
a main area;
a first edge area that is positioned on a first side of the main area in a first direction; and
a second edge area that is positioned a second side of the main area that is opposite from the first side in the first direction;
main area chip pads provided in the main area on a first line and a second line that extend in the first direction; and
edge area chip pads provided in first and second edge areas,
wherein the edge area chip pads are arranged such that two edge area chip pads immediately adjacent to each other in the first direction are spaced apart from each other in a second direction intersecting the first direction.

13. The semiconductor chip of claim 12, wherein respective lengths of the first edge area and the second edge area in the first direction are in each a range between 6% and 10%, inclusive of a total length of the semiconductor chip in the first direction.

14. The semiconductor chip of claim 13, wherein the length of the second edge area in the first direction is equal the length of the first edge area in the first direction.

15. The semiconductor chip of claim 12, wherein the edge area chip pads are alternately arranged on a third line and the first line, and are alternately arranged on a fourth line and the second line, the third and fourth lines extending in the first direction.

16. The semiconductor chip of claim 15, wherein the third line is positioned on the opposite side of the first line with respect to the second line, and wherein the fourth line is positioned on the opposite side of the second line with respect to the first line, and wherein the first line is closer to the third line than to the second line, and the second line is closer to the fourth line than to the first line.

17. The semiconductor chip of claim 16, wherein a length of a distance between the second line and the fourth line is equal to a length of a distance between the first line and the third line.

18. The semiconductor chip of claim 15, wherein at least one of the third line and the fourth line is positioned between the first line and the second line.

19. A semiconductor package comprising:
a substrate;
a semiconductor chip on the substrate; and
chip terminals that couple the semiconductor chip to the substrate,
wherein the semiconductor chip comprises:
a main area; and
an edge area positioned on a first side of the main area in a first direction;
main area chip pads provided on the main area; and
edge area chip pads provided on the edge area,
wherein the edge area chip pads are arranged such that two edge area chip pads immediately adjacent to each other in the first direction are spaced apart from each other in a direction intersecting the first direction.

20. The semiconductor package of claim 19, wherein a length of the edge area in the first direction is in a range between 6% and 10%, inclusive, of a total length of the semiconductor chip in the first direction.
